(19) United States
(12) Patent Application Publication
(10) Pub. No.: US 2025/0331341 A1
(43) Pub. Date: Oct. 23, 2025

(54) MICRO LIGHT-EMITTING DEVICE DISPLAY APPARATUS

(71) Applicant: PlayNitride Display Co., Ltd., MiaoLi County (TW)

(72) Inventors: Yi-Ching Chen, MiaoLi County (TW); Yu-Yun Lo, MiaoLi County (TW)

(73) Assignee: PlayNitride Display Co., Ltd., MiaoLi County (TW)

(21) Appl. No.: 18/666,739

(22) Filed: May 16, 2024

(30) Foreign Application Priority Data
Apr. 18, 2024 (TW) 113114444

(51) Int. Cl. H01L 33/62; H01L 25/075; H01L 33/08; H01L 33/18; H01L 33/30; H01L 33/50

(52) U.S. Cl. CPC H10H 20/857; H01L 25/0753; H10H 20/813; H10H 20/818; H10H 20/824; H10H 20/8515

(57) ABSTRACT

A micro light-emitting device display apparatus includes a plurality of micro light-emitting devices. Each micro light-emitting device includes a first light-emitting layer including a first epitaxial structure configured to emit light of a first wavelength and a second light-emitting layer bonded and stacked onto the first light-emitting layer through a metal layer, and including a second epitaxial structure configured to emit light of a second wavelength and a third epitaxial structure configured to emit light of a third wavelength. The second epitaxial structure and the third epitaxial structure are nanorod arrays of a same epitaxial material. The third wavelength is greater than the second wavelength. Both the second wavelength and the third wavelength are less than the first wavelength. A sum of orthographic projection areas of the second epitaxial structure and the third epitaxial structure is less than an orthographic projection area of the first epitaxial structure.

### CROSS-REFERENCE TO RELATED APPLICATION

This application claims the priority benefit of Taiwan application serial no. 113114444, filed on Apr. 18, 2024. The entirety of the above-mentioned patent application is hereby incorporated by reference herein and made a part of this specification.

### BACKGROUND

### Technical Field

The disclosure relates to a display apparatus, and particularly relates to a micro light-emitting device display apparatus.

### Description of Related Art

With the advancement of display technology, displays are not only developing in the direction of large size, but also in the direction of small size. For example, head-mounted displays that have attracted much attention nowadays use small-sized display panels. The head-mounted display is, for example, a virtual reality (VR) display, an augmented reality (AR) display, or a mixed reality (MR) display. In addition, in addition to the head-mounted displays, the augmented reality displays can also be applied to head-up displays (HUD), which also use the small-sized display panels. In addition, projectors or micro-projectors also use the small-sized display panels.

The small-sized display panels require high resolution and full color, especially for wearable devices, which require a thin and light design. Traditionally, in order to meet the requirements of full color and high resolution, red sub-pixels, green sub-pixels, and blue sub-pixels are arranged in a vertical stacking manner. However, since the wiring needs to sacrifice the light-emitting area or occupy a very limited spacing between pixels, it is difficult to design three-color stacked wiring in the limited pixel space under the demand for increasingly higher resolutions.

### SUMMARY

The disclosure provides a micro light-emitting device display apparatus, which can maintain a large light-emitting area and high spatial resolution, improve light-emitting efficiency, and reduce the impact of alignment tolerances during vertical stacking.

An embodiment of the disclosure provides a micro light-emitting device display apparatus, which includes a plurality of micro light-emitting devices, in which each micro light-emitting device includes a first light-emitting layer and a second light-emitting layer. The first light-emitting layer includes a first epitaxial structure configured to emit light of a first wavelength. The second light-emitting layer is bonded and stacked onto the first light-emitting layer through a metal layer. The second light-emitting layer includes a second epitaxial structure and a third epitaxial structure. The second epitaxial structure is configured to emit light of a second wavelength and the third epitaxial structure is configured to emit light of a third wavelength. The second epitaxial structure and the third epitaxial structure are nanorod arrays of a same epitaxial material. The third wavelength is greater than the second wavelength, and both the second wavelength and the third wavelength are less than the first wavelength. A sum of orthographic projection areas of the second epitaxial structure and the third epitaxial structure is less than an orthographic projection area of the first epitaxial structure.

An embodiment of the disclosure provides a micro light-emitting device display apparatus, including a first light-emitting layer, a second light-emitting layer, and a wavelength conversion structure. The first light-emitting layer includes a first epitaxial structure having a first part and a second part, both of which emit light of a first wavelength. The second light-emitting layer is stacked onto the first light-emitting layer. The second light-emitting layer includes a second epitaxial structure bonded onto the first part through a metal layer to emit light of a second wavelength. The wavelength conversion structure is stacked onto the second part and configured to convert the light of the first wavelength emitted by the second part into light of a third wavelength. An orthographic projection area of the second epitaxial structure is less than an orthographic projection area of the first part. In some embodiments, the first part and the second part of the first epitaxial structure are electrically independent, so as to be driven by different signals respectively, and both emit the light of the first wavelength.

In the micro light-emitting device display apparatus according to the embodiment of the disclosure, since a stacked structure of the first light-emitting layer and the second light-emitting layer is adopted, and the second light-emitting layer can emit light of two different wavelengths, the spatial resolution of the display pixel can be improved while the space required for the circuit wiring can be reduced to increase the light-emitting area. In addition, in the micro light-emitting device according to the embodiment of the disclosure, the sum of the orthographic projection areas of the second epitaxial structure and the third epitaxial structure is less than the orthographic projection area of the first epitaxial structure, or the orthographic projection area of the second epitaxial structure is less than the orthographic projection area of the first part, so the sub-pixels in the second light-emitting layer only cover a part of the sub-pixels in the first light-emitting layer such that the light-emitting efficiency can be improved. Furthermore, in the micro light-emitting device display apparatus according to the embodiment of the disclosure, the first light-emitting layer and the second light-emitting layer are connected by bonding through the metal layer, so that the second epitaxial structure and the third epitaxial structure can be disposed on the first light-emitting layer simultaneously in a single process step. Compared with the requirement of two yellow photolithography processes to define the epitaxial region when separately manufacturing the second epitaxial structure and the third epitaxial structure, it is possible to reduce a one-time alignment step, thereby reducing the impact of alignment tolerances during vertical stacking.

### BRIEF DESCRIPTION OF THE DRAWINGS

FIG. 1A is a schematic cross-sectional view of a micro light-emitting device according to an embodiment of the disclosure.

FIG. 1B is a partial schematic cross-sectional view of a nanorod array of the second epitaxial structure of FIG. 1A.

FIG. 1C is a partial schematic cross-sectional view of a nanorod array of the third epitaxial structure of FIG. 1A.

FIG. 1D is a schematic cross-sectional view of a micro light-emitting device according to yet another embodiment of the disclosure.

FIG. 2A is a schematic top view of a micro light-emitting device according to another embodiment of the disclosure.

FIG. 2B is a schematic cross-sectional view of the micro light-emitting device of FIG. 2A along a line A-A′.

FIG. 2C is a schematic cross-sectional view of the micro light-emitting device of FIG. 2A along a line B-B′.

FIG. 3A is a schematic top view of a micro light-emitting device according to still another embodiment of the disclosure.

FIG. 3B is a schematic cross-sectional view of the micro light-emitting device of FIG. 3A along a line A-A′.

FIG. 4A is a schematic cross-sectional view of a micro light-emitting device according to another embodiment of the disclosure.

FIG. 4B is a partial schematic cross-sectional view of a nanorod array of the first epitaxial structure and a nanorod array of the second epitaxial structure of FIG. 1A.

FIG. 5A is a schematic top view of a micro light-emitting device according to still another embodiment of the disclosure.

FIG. 5B is a schematic cross-sectional view of the micro light-emitting device of FIG. 5A along a line A-A′.

FIG. 6A is a schematic top view of a micro light-emitting device according to yet another embodiment of the disclosure.

FIG. 6B is a schematic cross-sectional view of the micro light-emitting device of FIG. 6A along a line A-A′.

FIG. 7 is a partial schematic top view of a micro light-emitting device display apparatus according to an embodiment of the disclosure.

FIG. 8 is a flowchart of a manufacturing method of a micro light-emitting device according to an embodiment of the disclosure.

FIG. 9 is a flowchart of a manufacturing method of a micro light-emitting device according to another embodiment of the disclosure.

### DESCRIPTION OF THE EMBODIMENTS

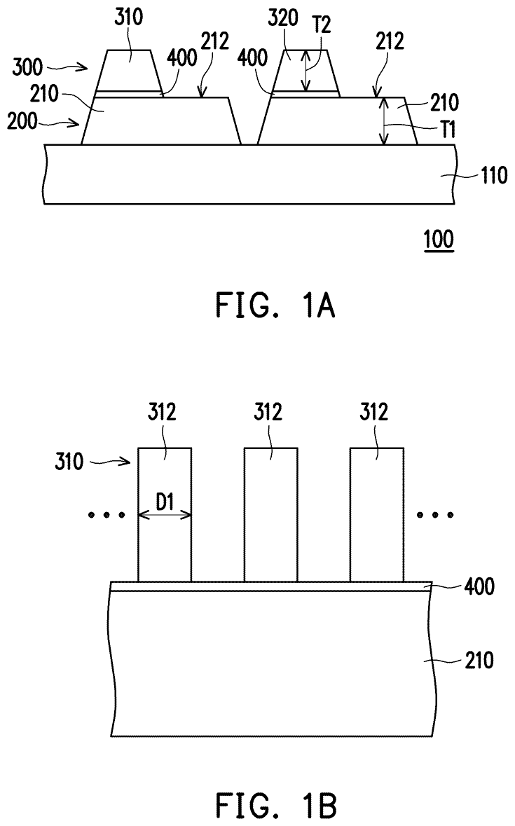

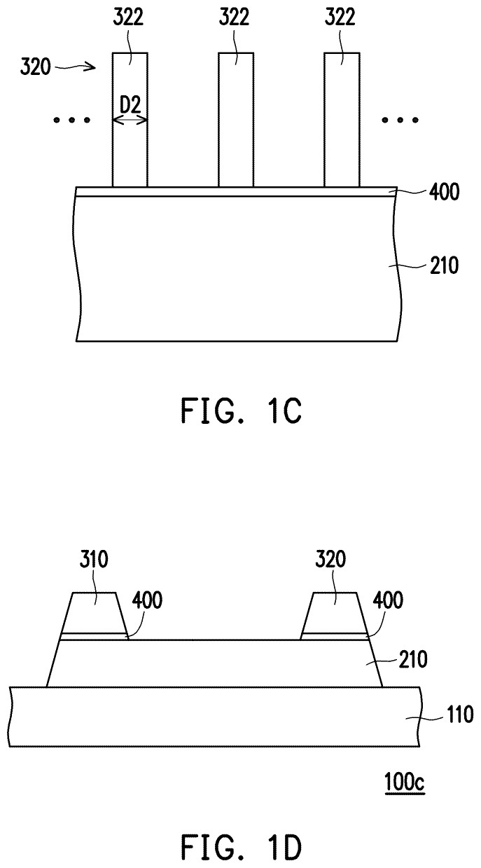

FIG. 1A is a schematic cross-sectional view of a micro light-emitting device according to an embodiment of the disclosure. FIG. 1B is a partial schematic cross-sectional view of a nanorod array of the second epitaxial structure of FIG. 1A. FIG. 1C is a partial schematic cross-sectional view of a nanorod array of the third epitaxial structure of FIG. 1A. Referring to FIG. 1A, FIG. 1B, and FIG. 1C, a micro light-emitting device 100 of the embodiment is disposed on a substrate 110. The micro light-emitting device 100 includes a first light-emitting layer 200 and a second light-emitting layer 300. The first light-emitting layer 200 includes a first epitaxial structure 210 configured to emit light of a first wavelength, such as red light. The second light-emitting layer 300 is bonded and stacked onto the first light-emitting layer 200 through a metal layer 400. The second light-emitting layer 300 includes a second epitaxial structure 310 and a third epitaxial structure 320. The second epitaxial structure 310 is configured to emit light of a second wavelength, such as blue light. The third epitaxial structure 320 is configured to emit light of a third wavelength, such as green light. The third wavelength is greater than the second wavelength. The second epitaxial structure 310 and the third epitaxial structure 320 are nanorod arrays of a same epitaxial material. For example, the second epitaxial structure 310 includes a plurality of nanorods 312 arranged in an array (for example, a two-dimensional array), and the third epitaxial structure 320 includes a plurality of nanorods 322 arranged in an array (for example, a two-dimensional array). In the embodiment, the nanorods 312 and the nanorods 322 stand upright on the first epitaxial structure 210.

In the embodiment, a material of the second epitaxial structure 310 and the third epitaxial structure 320 is, for example, indium gallium nitride (InGaN) or gallium nitride (GaN). The indium concentration of the second epitaxial structure 310 is greater than the indium concentration of the third epitaxial structure 320, which can be achieved by adjusting the indium concentration in different regions during the manufacturing process. When the indium concentration in a region is higher, a diameter of the nanorods formed in this region is larger. Therefore, in the embodiment, a diameter of a single nanorod in the nanorod array of the second epitaxial structure 310 (i.e., a diameter D1 of the nanorod 312) is greater than a diameter of a single nanorod in the nanorod array of the third epitaxial structure 320 (i.e., a diameter D2 of the nanorod 322). Furthermore, the smaller the diameter of the nanorod, the longer the wavelength of the light it emits. Therefore, the third wavelength (i.e., the wavelength of the light emitted by the third epitaxial structure 320) is greater than the second wavelength (i.e., the wavelength of the light emitted by the second epitaxial structure 310). In addition, in the embodiment, the first wavelength (that is, the wavelength of the light emitted by the first epitaxial structure 210) is greater than the third wavelength. That is to say, both the second wavelength and the third wavelength are less than the first wavelength. In an embodiment, the light of the first wavelength is red light, the light of the second wavelength is blue light, and the light of the third wavelength is green light. In the embodiment, the first epitaxial structure 210 may have a nanorod array, or may be a continuous film layer.

In the embodiment, the sum of orthographic projection areas of the second epitaxial structure 310 and the third epitaxial structure 320 is less than an orthographic projection area of the first epitaxial structure 210. The “orthographic projection” and “orthographic projection area” here or elsewhere in the specification refer to the orthographic projection and orthographic projection area on the substrate 110, that is to say, the sum of the orthographic projection areas of the second epitaxial structure 310 and the third epitaxial structure 320 on the substrate 110 is less than the orthographic projection area of the first epitaxial structure 210 on the substrate 110. A light-emitting surface 212 exposed by the first light-emitting layer 200 is not blocked by the second epitaxial structure 310 and the third epitaxial structure 320, and can emit light with higher efficiency.

In the micro light-emitting device 100 of the embodiment, since a stacked structure of the first light-emitting layer 200 and the second light-emitting layer 300 is adopted, and the second light-emitting layer 300 can emit light of two different wavelengths, the micro light-emitting device 100, when used as a display pixel, can improve the spatial resolution of the display pixel and reduce the space required for the circuit wiring, especially the wiring in the horizontal direction, to increase the light-emitting area. In the embodiment, in order for the second light-emitting layer 300 to be stably stacked onto the first light-emitting layer 200, the orthographic projection area of the first light-emitting layer 200 must be sufficient to simultaneously carry the second epitaxial structure 310 and the third epitaxial structure 320. When the second epitaxial structure 310 is a blue light-emitting diode and the third epitaxial structure 320 is a green light-emitting diode, both have similar light-emitting efficiencies. At this time, the orthographic projection areas of the second epitaxial structure 310 and the third epitaxial structure 320 are similar, so each of them occupies at most ½ of the orthographic projection area of the first epitaxial structure 210. That is, the orthographic projection area of the second epitaxial structure 310 is less than ½ of the orthographic projection area of the first epitaxial structure 210, and the orthographic projection area of the third epitaxial structure 320 is less than ½ of the orthographic projection area of the first epitaxial structure 210. In addition, in the micro light-emitting device 100 of the embodiment, the sum of the orthographic projection areas of the second epitaxial structure 310 and the third epitaxial structure 320 is less than the orthographic projection area of the first epitaxial structure 210, so the sub-pixels in the second light-emitting layer 300 only cover a part of the sub-pixels in the first light-emitting layer 200 such that the light-emitting efficiency can be improved. In some embodiments, the first epitaxial structure 210 is a red light-emitting diode, the second epitaxial structure 310 is a blue light-emitting diode, and the third epitaxial structure 320 is a green light-emitting diode. In order to enable the first epitaxial structure 210 with a lower light-emitting efficiency to emit light sufficient to achieve a white balance with the second epitaxial structure 310 and the third epitaxial structure 320, the light-emitting area exposed by the first epitaxial structure 210 should be two times or greater than the second epitaxial structure 310 or the third epitaxial structure 320 respectively. That is, the sum of the orthographic projection areas of the second epitaxial structure 310 and the third epitaxial structure 320 is less than ½ of the orthographic projection area of the first epitaxial structure 210. Furthermore, in the micro light-emitting device 100 of the embodiment, the first light-emitting layer 200 and the second light-emitting layer 300 are connected by bonding through the metal layer 400, so that the second epitaxial structure 310 and the third epitaxial structure 320 can be disposed on the first light-emitting layer 200 simultaneously in a single process step. Compared with the requirement of two yellow photolithography processes to define the epitaxial region when separately manufacturing the second epitaxial structure 310 and the third epitaxial structure 320, it is possible to reduce a one-time alignment step, thereby reducing the impact of alignment tolerances during vertical stacking.

In the embodiment, a thickness T1 of the first light-emitting layer 200 or a thickness T2 of the second light-emitting layer 300 falls within a range of 1 micron to 2 microns. In addition, in the embodiment, the metal layer 400 is disposed in the region where the second epitaxial structure 310 or the third epitaxial structure 320 is bonded onto the first epitaxial structure 210 such that a part of the light-emitting surface 212 of the first epitaxial structure 210 is exposed. The metal layer 400 also serves as a reflective layer configured to reflect the light of the first wavelength to the light-emitting surface 212 for emission.

FIG. 1D is a schematic cross-sectional view of a micro light-emitting device according to yet another embodiment of the disclosure. Referring to FIG. 1D, a micro light-emitting device 100c of the embodiment is similar to the micro light-emitting device 100 of FIG. 1A, and the main differences between the two are as follows. In the micro light-emitting device 100 of FIG. 1A, the first epitaxial structure 210 is divided into two separate pieces located below the second epitaxial structure 310 and the third epitaxial structure 320 respectively. However, in the micro light-emitting device 100c of FIG. 1D, a first epitaxial structure 210c is a piece connected together, and the second epitaxial structure 310 and the third epitaxial structure 320 are arranged thereon.

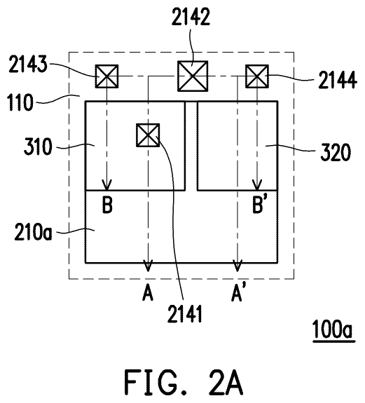

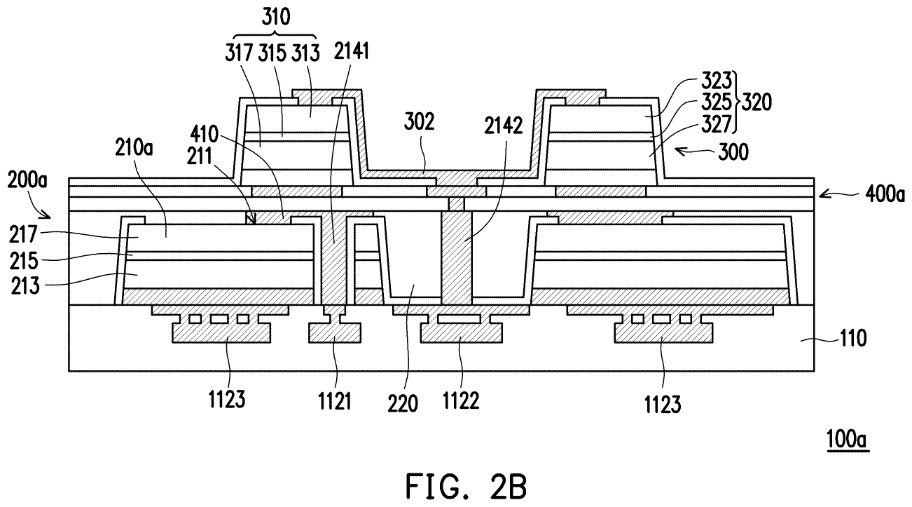

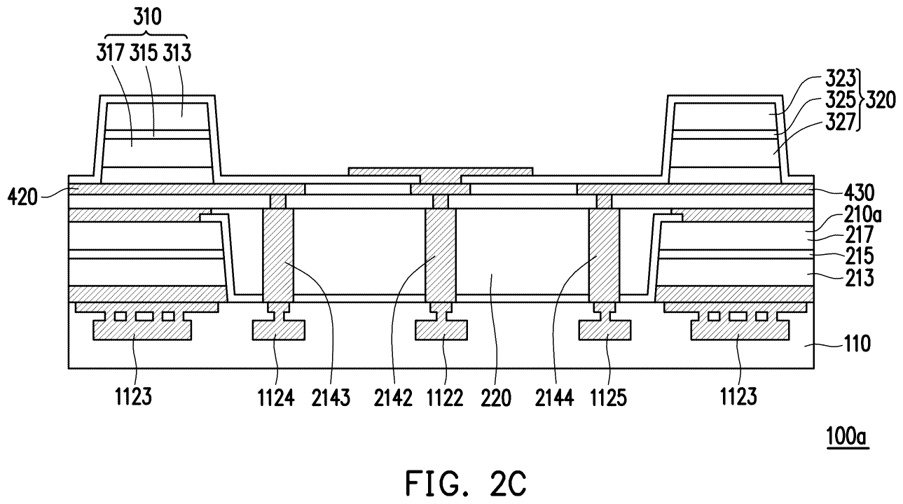

FIG. 2A is a schematic top view of a micro light-emitting device according to another embodiment of the disclosure. FIG. 2B is a schematic cross-sectional view of the micro light-emitting device of FIG. 2A along a line A-A′. FIG. 2C is a schematic cross-sectional view of the micro light-emitting device of FIG. 2A along a line B-B′. Referring to FIG. 2A to FIG. 2C, a micro light-emitting device 100a of the embodiment is similar to the micro light-emitting device 100 of FIG. 1A, and the main differences between the two are as follows. In the micro light-emitting device 100a of the embodiment, a first epitaxial structure 210a has a conductive via 2141 configured to electrically connect in a vertical direction an external pad 1121 (for example, a positive electrode) of the substrate 110 and a side 211 of the first epitaxial structure 210 close to the second light-emitting layer 300. Specifically, the first epitaxial structure 210a includes a first type semiconductor layer 213, an active layer 215, and a second type semiconductor layer 217 stacked in sequence, the second epitaxial structure 310 includes a second type semiconductor layer 317, an active layer 315, and a first type semiconductor layer 313 stacked in sequence, and the third epitaxial structure 320 includes a second type semiconductor layer 327, an active layer 325, and a first type semiconductor layer 323 stacked in sequence. In the embodiment, the first type is N type, and the second type is P type. However, in other embodiments, the first type may be P type, and the second type may be N type. In addition, in the embodiment, the active layers 215, 315, and 325 are, for example, quantum well layers or a plurality of quantum well layers, which can respectively emit light of the first wavelength, light of the second wavelength, and light of the third wavelength. In an embodiment not shown, the active layer 315 of the second epitaxial structure 310 and the active layer 325 of the third epitaxial structure 320 include a plurality of non-epitaxial media. A material of the non-epitaxial medium is, for example, silicon dioxide, silicon nitride, or metal oxide, and the non-epitaxial medium is a plurality of insulation patterns. The epitaxial media are separated from each other to disperse indium and control the aggregation degree of indium in the active layers, thereby modulating the color light emitted by the active layer 315 or the active layer 325. A horizontal distance between any two adjacent non-epitaxial media is less than 100 nanometers. Two adjacent non-epitaxial media in the active layer 315 have a first spacing, two adjacent non-epitaxial media in the active layer 325 have a second spacing, and the second spacing is greater than the first spacing, so that the active layer 315 emits blue light with a shorter wavelength, and the active layer 325 emits green light with a longer wavelength.

In the embodiment, a lower side of the first type semiconductor layer 213 is electrically connected to an external pad 1123, which is a negative electrode, and the external pad 1121 (the positive electrode) is electrically connected to the second type semiconductor layer 217 through the conductive via 2141. The conductive via 2141 is composed of a conductive material filled in the through hole, such as metal (other conductive vias in this specification are composed of a conductive material filled in the through hole). Therefore, when a forward voltage is applied to the external pad 1121 and the external pad 1123, the active layer 215 can be configured to emit light of the first wavelength.

On the other hand, a first light-emitting layer 200a may have a conductive via 2142 configured to electrically connect in a vertical direction an external pad 1122 (for example, a negative electrode) on the substrate 110 and the second light-emitting layer 300. The conductive via 2142, for example, electrically connects the external pad 1122 and the first type semiconductor layer 313 and also electrically connects the external pad 1122 and the first type semiconductor layer 323 through a trace layer 302. In addition, the first light-emitting layer 200a may have a conductive via 2143 to electrically connect an external pad 1124 (for example, a positive electrode) and the second type semiconductor layer 317. When a forward voltage is applied to the external pad 1124 and the external pad 1122, the active layer 315 can be configured to emit light of the second wavelength. In the embodiment, the orthographic projection of the conductive via 2142 at least partially overlaps the orthographic projection of the external pad 1122.

In addition, the first light-emitting layer 200a may have a conductive via 2144 to electrically connect an external pad 1125 (for example, a positive electrode) and the second type semiconductor layer 327. When a forward voltage is applied to the external pad 1125 and the external pad 1122, the active layer 325 can be configured to emit light of the third wavelength.

In the embodiment, the external pads 1121, 1122, 1123, 1124, and 1125 are located in the substrate 110. The substrate 110 is, for example, a silicon substrate. However, in other embodiments, the substrate 110 may also be a glass substrate, a plastic substrate, or a substrate of other materials.

In the embodiment, the top of the conductive via 2141 is connected to the top of the second type semiconductor layer 217 through a metal layer 410, the top of the conductive via 2143 is connected to the bottom of the second type semiconductor layer 317 through a metal layer 420, and the top of the conductive via 2144 is connected to the bottom of the second type semiconductor layer 327 through a metal layer 430. An insulating layer 440 is provided between the metal layer 410 and the metal layer 420, and the insulating layer 440 is also located between the metal layer 410 and the metal layer 430. The metal layers 410, 420, and 430 and the insulating layer 440 form a metal layer 400a that bonds the first light-emitting layer 200a and the second light-emitting layer 300. In the embodiment, the conductive vias 2142, 2143, and 2144 penetrate through an insulating layer 220 of the first light-emitting layer 200a in a vertical direction. In the embodiment, a position of the conductive via 2141 in an orthographic projection direction at least partially overlaps a position of the external pad 1121 in an orthographic projection direction. In some embodiments, a position of the conductive via 2142 in an orthographic projection direction at least partially overlaps a position of the external pad 1122 in an orthographic projection direction. For example, when making an electrical connection, the two can be directly bonded after alignment without relying on an additional horizontal circuit to connect, so as to save space for setting up horizontal circuits to further reduce the spacing between pixels.

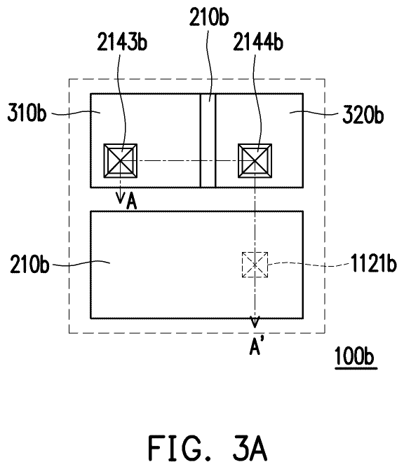

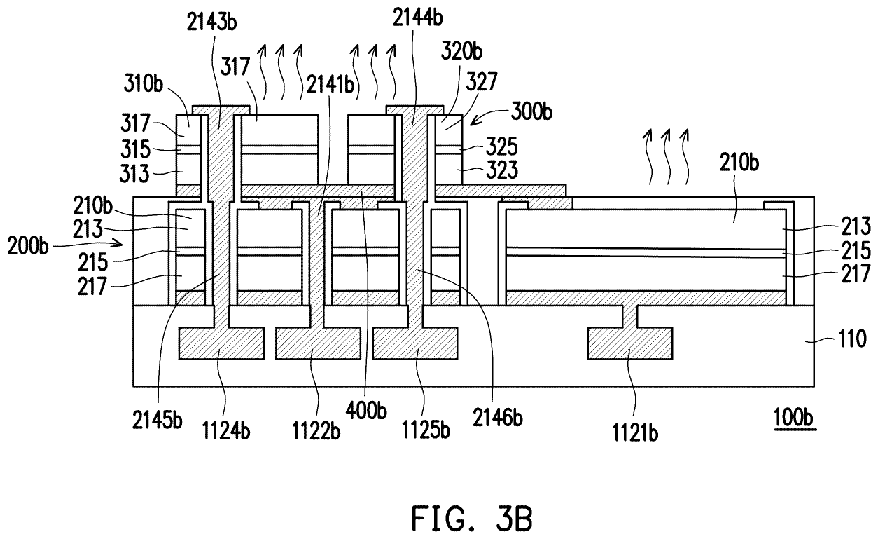

FIG. 3A is a schematic top view of a micro light-emitting device according to still another embodiment of the disclosure. FIG. 3B is a schematic cross-sectional view of the micro light-emitting device of FIG. 3A along a line A-A′. Referring to FIG. 3A and FIG. 3B, a micro light-emitting device 100b of the embodiment is similar to the micro light-emitting device 100a of FIG. 2A to FIG. 2C, and the main differences between the two are as follows. In the micro light-emitting device 100b of the embodiment, a first epitaxial structure 210b has a conductive via 2141b configured to electrically connect in a vertical direction an external pad 1122b and a second light-emitting layer 300b. Specifically, the first epitaxial structure 210b has the second type semiconductor layer 217, the active layer 215, and the first type semiconductor layer 213 stacked in sequence, a second epitaxial structure 310b has the first type semiconductor layer 313, the active layer 315, and the second type semiconductor layer 317 stacked in sequence, and a third epitaxial structure 320b has the first type semiconductor layer 323, the active layer 325, and the second type semiconductor layer 327 stacked in sequence. The conductive via 2141b connects the external pad 1122b (for example, a negative electrode) and the first type semiconductor layer 213, the first type semiconductor layer 313, and the first type semiconductor layer 323 through a metal layer 400b. That is to say, the metal layer 400b bonds the first epitaxial structure 210b and the second epitaxial structure 310b, and bonds the first epitaxial structure 210b and the third epitaxial structure 320b.

On the other hand, a lower side of the second type semiconductor layer 217 is electrically connected to an external pad 1121b (for example, a positive electrode). When a forward voltage is applied between the external pad 1121b and the external pad 1122b, the active layer 215 can be configured to emit light of the first wavelength.

In the embodiment, the second epitaxial structure 310b has a conductive via 2143b configured to electrically connect in a vertical direction an external pad 1124b (for example, a positive electrode) and a side of the second epitaxial structure 310b away from a first light-emitting layer 200b. In the embodiment, the conductive via 2143b is electrically connected to the external pad 1124b on the substrate 110 through a conductive via 2145b of the first epitaxial structure 210b. The conductive via 2143b also penetrates through the first epitaxial structure 210b and the top of the conductive via 2143b is electrically connected to the second type semiconductor layer 317. When a forward voltage is applied between the external pad 1124b and the external pad 1122b, the active layer 315 can be configured to emit light of the second wavelength.

In the embodiment, the third epitaxial structure 320b has a conductive via 2144b configured to electrically connect in a vertical direction an external pad 1125b (for example, a positive electrode) on the substrate 110 and a side of the third epitaxial structure 320b away from the first light-emitting layer 200b. In the embodiment, the conductive via 2144b is electrically connected to the external pad 1125b on the substrate 110 through a conductive via 2146b of the first epitaxial structure 210b. The conductive via 2144b also penetrates through the first epitaxial structure 210b, and the top of the conductive via 2144b is electrically connected to the second type semiconductor layer 327. When a forward voltage is applied between the external pad 1125band the external pad 1122b, the active layer 325 can be configured to emit light of the third wavelength.

In the embodiment, a part of the first epitaxial structure 210b does not have the second epitaxial structure 310b and the third epitaxial structure 320b disposed above (for example, the lower half of FIG. 3A and the right half of FIG. 3B). Therefore, the light of the first wavelength emitted by this part of the first epitaxial structure 210b will not be blocked by the second epitaxial structure 310b and the third epitaxial structure 320b, and can have good light-emitting efficiency.

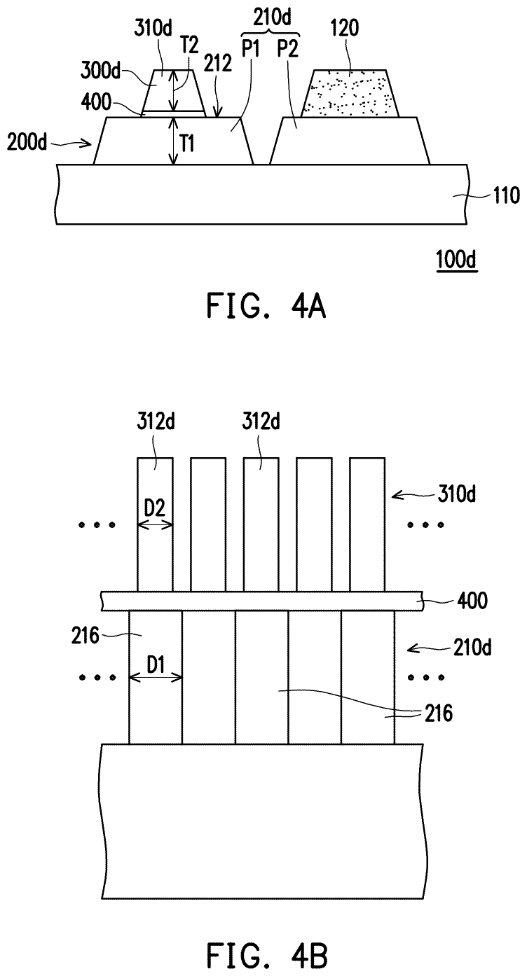

FIG. 4A is a schematic cross-sectional view of a micro light-emitting device according to another embodiment of the disclosure. Referring to FIG. 4A, a micro light-emitting device 100d of the embodiment is similar to the micro light-emitting device 100 of FIG. 1A, and the main differences between the two are as follows. The micro light-emitting device 100d of the embodiment includes a first light-emitting layer 200d, a second light-emitting layer 300d, and a wavelength conversion structure 120. The first light-emitting layer 200d includes a first epitaxial structure 210d having a first part P1 and a second part P2. The first part P1 and the second part P2 both emit light of the first wavelength. In the embodiment, the first part P1 and the second part P2 of the first epitaxial structure 210d are electrically independent of each other. The second light-emitting layer 300d is stacked onto the first light-emitting layer 200d. The second light-emitting layer 300d includes a second epitaxial structure 310d bonded onto the first part P1 through the metal layer 400 and emitting light of the second wavelength. The wavelength conversion structure 120 is stacked onto the second part P2 to convert the light of the first wavelength emitted by the second part P2 into light of the third wavelength. In the embodiment, the light of the first wavelength is, for example, blue light, the light of the second wavelength is, for example, green light, and the light of the third wavelength is, for example, red light. In the embodiment, the wavelength conversion structure 120 is, for example, a quantum dot layer or a fluorescent layer. The fluorescent layer can be a potassium fluorosilicate (KSF) fluorescent layer or a fluorescent layer of other materials, and the quantum dot layer or the fluorescent layer can convert the light of the first wavelength into the light of the third wavelength.

In the embodiment, a sum of orthographic projection areas of the second epitaxial structure 310d and the wavelength conversion structure 120 is less than an orthographic projection area of the first epitaxial structure 210d (including the first part P1 and a second part P2). That is to say, the sum of the orthographic projection areas of the second epitaxial structure 310d and the wavelength conversion structure 120 on the substrate 110 is less than the orthographic projection area of the first epitaxial structure 210d (including the first part P1 and a second part P2) on the substrate 110. In an embodiment, the orthographic projection area of the second epitaxial structure 310d is less than the orthographic projection area of the first part P1.

In the embodiment, the first epitaxial structure 210d and the second epitaxial structure 310d are solid grains of a same epitaxial material. In some embodiments, the first epitaxial structure 210d and the second epitaxial structure 310d are nanorod arrays of a same epitaxial material. As shown in FIG. 4B, the nanorod array of the first epitaxial structure 210d and the nanorod array of the second epitaxial structure 310d are stacked and bonded through the metal layer 400 as shown in the figure. For example, the first epitaxial structure 210d includes a plurality of nanorods 216 arranged in an array (for example, a two-dimensional array), and the second epitaxial structure 310d includes a plurality of nanorods 312d arranged in an array (for example, a two-dimensional array). In the embodiment, the nanorods 216 stand upright on the substrate 110, and the nanorods 312d stand upright on the metal layer 400.

In the embodiment, a material of the first epitaxial structure 210d and the second epitaxial structure 310d is, for example, indium gallium nitride (InGaN) or gallium nitride (GaN). The indium concentration of the first epitaxial structure 210d is greater than the indium concentration of the second epitaxial structure 310d. When the indium concentration is higher, the diameter of the formed nanorods is larger. Therefore, in the embodiment, a diameter of a single nanorod in the nanorod array of the first epitaxial structure 210d (i.e., a diameter D1 of the nanorod 216) is greater than a diameter of a single nanorod in the nanorod array of the second epitaxial structure 310d (i.e., a diameter D2 of the nanorod 312d). Furthermore, the smaller the diameter of the nanorod, the longer the wavelength of the light it emits. Therefore, the second wavelength (i.e., the wavelength of the light emitted by the second epitaxial structure 310d) is greater than the first wavelength (i.e., the wavelength of the light emitted by the first epitaxial structure 210d).

In some embodiments, the material of the first epitaxial structure 210d includes (AlxGa1-x)1-yInyP, that is, aluminum gallium indium phosphide, where 1≥x≥0, and 1>y>0. The second epitaxial structure 310d includes the plurality of nanorods 312d arranged in an array (such as a two-dimensional array). The material of the second epitaxial structure 310d is, for example, iudium gallium nitride (InGaN) or gallium nitride (GaN).

In the micro light-emitting device 100d of the embodiment, the sum of the orthographic projection areas of the second epitaxial structure 310d and the wavelength conversion structure 120 is less than the orthographic projection area of the first epitaxial structure 210d. Therefore, when the micro light-emitting device 100d is used as a display pixel, the sub-pixels in the second light-emitting layer 300d and the sub-pixels in the wavelength conversion structure 120 only cover a part of the sub-pixels in the first light-emitting layer 200d such that the light-emitting efficiency can be improved. In some embodiments, the orthographic projection area of the second epitaxial structure 310d is less than the orthographic projection area of the first part P1, and a light-emitting surface 212 exposed by the first part P1 is not blocked by the second epitaxial structure 310d, so that light is emitted with a higher efficiency. Furthermore, in the micro light-emitting device 100d of the embodiment, the first light-emitting layer 200d and the second light-emitting layer 300d are connected by bonding through the metal layer 400, thereby reducing the impact of alignment tolerances during vertical stacking.

In the embodiment, a thickness T1 of the first epitaxial structure 210d falls within a range of 1 micron to 2 microns. In the embodiment, a thickness T2 of the second epitaxial structure 300d falls within a range of 1 micron to 2 microns. In addition, in the embodiment, the metal layer 400 is disposed in the region where the second epitaxial structure 300d and the first epitaxial structure 210d are bonded, so that the light-emitting surface 212 of the first epitaxial structure 210d is exposed to reflect the light of the first wavelength to the light-emitting surface 212 for emission.

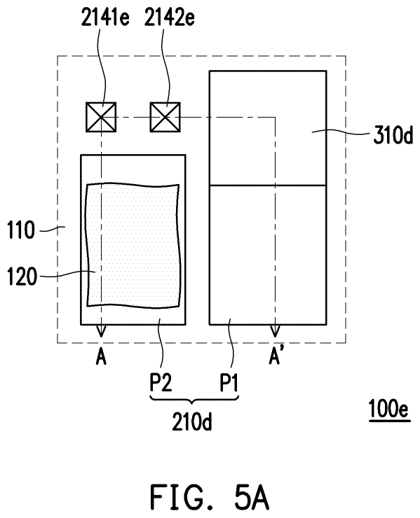

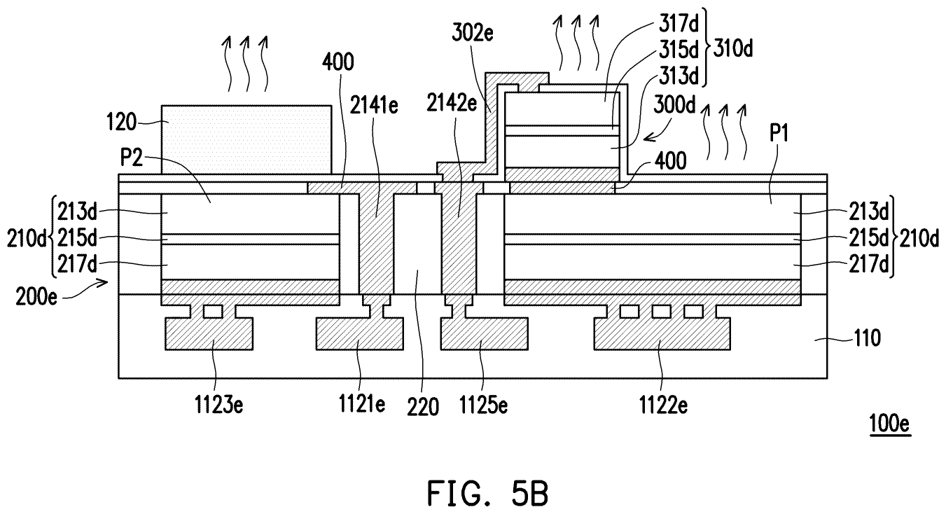

FIG. 5A is a schematic top view of a micro light-emitting device according to still another embodiment of the disclosure. FIG. 5B is a schematic cross-sectional view of the micro light-emitting device of FIG. 5A along a line A-A′. Referring to FIG. 5A and FIG. 5B, a micro light-emitting device 100e of the embodiment is similar to the micro light-emitting device 100d of FIG. 4A, and the main differences between the two are as follows. In the micro light-emitting device 100e of the embodiment, a first light-emitting layer 200e has a conductive via 2141e configured to electrically connect in a vertical direction an external pad 1121e of the substrate 110 and a side of the first epitaxial structure 210d close to the second light-emitting layer 300d, such as electrically connecting the external pad 1121e and a first type semiconductor layer 213d of the first epitaxial structure 210d, for example, through the metal layer 400. A lower side of a second type semiconductor layer 217d of a second part P2 of the first epitaxial structure 210d is electrically connected to an external pad 1123e. When a forward voltage is applied to the external pad 1123e and the external pad 1121e, an active layer 215d of the second part P2 of the first epitaxial structure 210d will emit light of the first wavelength. After irradiating the wavelength conversion structure 120 above, light of the second wavelength will be converted into light of the third wavelength by the wavelength conversion structure 120. The lower side of the second type semiconductor layer 217d of a first part P1 of the first epitaxial structure 210d is electrically connected to an external pad 1122e. When a forward voltage is applied to the external pad 1122eand the external pad 1121e, the active layer 215d of the first part P1 of the first epitaxial structure 210d will emit light of the first wavelength.

On the other hand, the conductive via 2141e is also electrically connected to a first type semiconductor layer 313d of the second epitaxial structure 310d through the metal layer 400. In addition, the first light-emitting layer 200e also has a conductive via 2142e configured to electrically connect in a vertical direction another external pad 1125e on the substrate 110 and the second light-emitting layer 300d. For example, the conductive via 2142e is electrically connected to a second type semiconductor layer 317d of the second epitaxial structure 310dthrough a trace layer 302e. Furthermore, the conductive via 2141e electrically connects an external pad 1125e and the second type semiconductor layer 317d. When a forward voltage is applied to the external pad 1125e and the external pad 1121e, the active layer 315d of the second epitaxial structure 310d will emit light of the second wavelength. In the embodiment, the conductive vias 2141e and 2142e penetrate through an insulating layer 220 of the first light-emitting layer 200e, and the conductive vias 2141e and 2142e are arranged on the sides of the first part P1 or the second part P2. In the embodiment, the orthographic projection area of the wavelength conversion structure 120 covers the orthographic projection area of the second part P2.

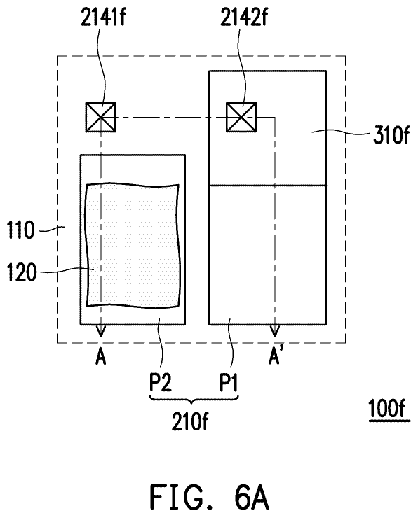

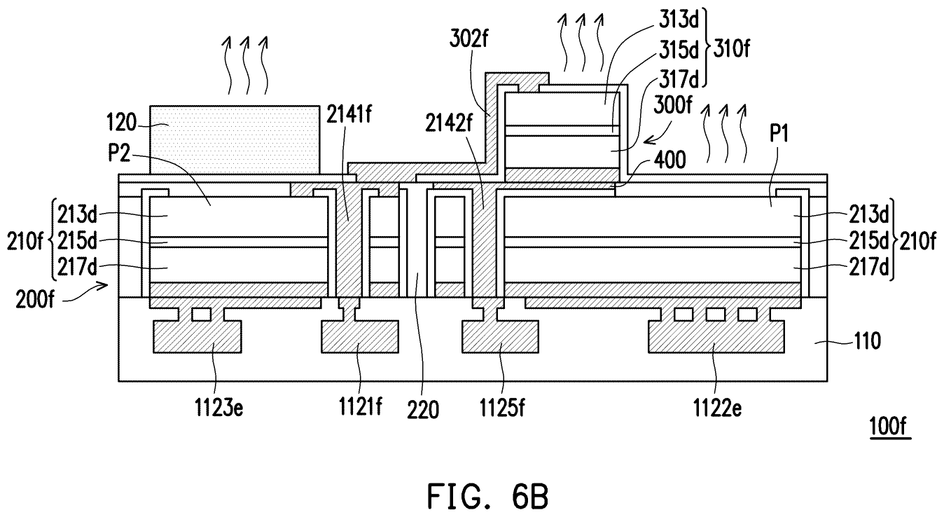

FIG. 6A is a schematic top view of a micro light-emitting device according to yet another embodiment of the disclosure. FIG. 6B is a schematic cross-sectional view of the micro light-emitting device of FIG. 6A along a line A-A′. Referring to FIG. 6A and FIG. 6B, a micro light-emitting device 100f of the embodiment is similar to the micro light-emitting device 100e of FIG. 5A and FIG. 5B, and the main differences between the two are as follows. In the micro light-emitting device 100f of the embodiment, a first epitaxial structure 210f of a first light-emitting layer 200f has a conductive via 2141f configured to electrically connect in a vertical direction an external pad 1121f and a side of the first epitaxial structure 210f close to a second light-emitting layer 300f, such as electrically connecting the external pad 1121f and the first type semiconductor layer 213d of the first epitaxial structure 210f. In the embodiment, the first epitaxial structure 210f has a conductive via 2142f configured to electrically connect an external pad 1125f and a second epitaxial structure 310f, such as electrically connecting the external pad 1125f and the second type semiconductor layer 317d of the second epitaxial structure 310f. On the other hand, the conductive via 2141f is also electrically connected to the first type semiconductor layer 313d of the second epitaxial structure 310f through a trace layer 302f. When a forward voltage is applied to the external pad 1125f and the external pad 1121f, the active layer 315d of the second epitaxial structure 310f will emit light of the second wavelength.

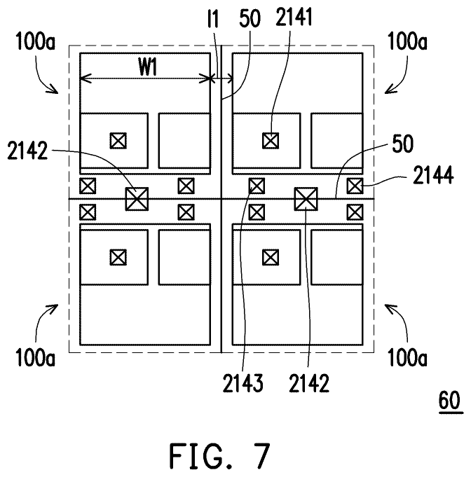

FIG. 7 is a partial schematic top view of a micro light-emitting device display apparatus according to an embodiment of the disclosure. Referring to FIG. 7, in the embodiment, a micro light-emitting device display apparatus 60 includes a plurality of micro light-emitting devices 100a, and a distance I1 between adjacent micro light-emitting devices 100a is less than a size of the micro light-emitting device 100a (such as a width W1 of the micro light-emitting device 100a). In addition, in the embodiment, there is a blocking wall 50 between adjacent micro light-emitting devices 100a to reduce light crosstalk. The blocking wall 50 can be formed of a light-absorbing material or a reflective material. In addition, in the embodiment, adjacent micro light-emitting devices 100a may share part of the conductive vias and part of the external pads, such as sharing the conductive vias 2142 and the connected external pads 1122 (as shown in FIG. 2B). In some embodiments, the conductive via 2143 and the conductive via 2144 are disposed on the side of the first part P1 or the second part P2 of the first epitaxial structure 210. The plurality of micro light-emitting devices 100a are arranged in an array to form a pixel array of the micro light-emitting device display apparatus 60, that is, each micro light-emitting device 100a is a pixel. In other embodiments, the number of the micro light-emitting devices 100 and 100b to 100f of the other embodiments can also be plural and arranged in an array to form a pixel array of the micro light-emitting device display apparatus 60. In some embodiments, a single micro light-emitting device 100a occupies an area ratio of greater than or equal to 70% of the pixel to which it belongs in the orthographic projection direction.

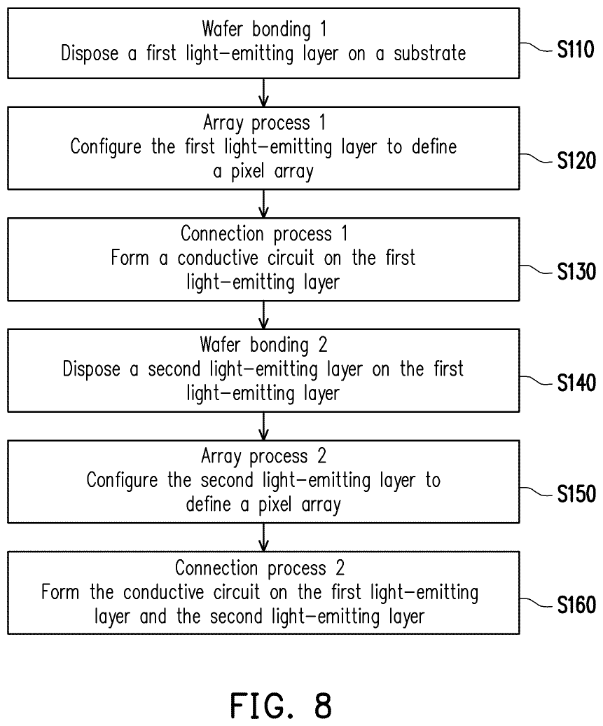

FIG. 8 is a flowchart of a manufacturing method of a micro light-emitting device according to an embodiment of the disclosure. Referring to FIG. 8, the manufacturing method of the micro light-emitting device of the embodiment can be configured to manufacture the micro light-emitting devices 100 and 100a to 100c of each embodiment of FIG. 1A to FIG. 1D. In the following, the manufacturing of the micro light-emitting device 100a of FIG. 2A to FIG. 2C is mainly taken as an example for description. The manufacturing method of the micro light-emitting device of the embodiment includes the following steps. First, step S110 is performed, which is a wafer bonding process to dispose the first light-emitting layer 200a on the substrate 110. The substrate 110 is, for example, a circuit substrate, and the first light-emitting layer 200a includes the first type semiconductor layer 213, the active layer 215, and the second type semiconductor layer 217. The wafer bonding process can be performed by metal bonding, which can reduce the impact of alignment errors. Next, step S120 is performed, which is an array process to configure the first light-emitting layer 200a to define a pixel array, such as the first epitaxial structure 210a as shown in FIG. 2B. Then, step S130 is performed, which is a connection process to form a conductive circuit on the first light-emitting layer 200a, such as the conductive vias 2141, 2142, 2143, and 2144 or trace layers. After that, step S140 is performed, which is a wafer bonding process to dispose the second light-emitting layer 300 on the first light-emitting layer 200a. For example, the first light-emitting layer 200a and the second light-emitting layer 300 are bonded through the metal layer 400a, so that the impact of alignment errors can be reduced by the metal bonding method. After that, step S150 is performed, which is an array process, in which a plurality of epitaxial structures are divided at positions corresponding to the display pixels to configure the second light-emitting layer 300 to define a pixel array, such as the second epitaxial structure 310 and the third epitaxial structure 320 as shown in FIG. 2B, and the second light-emitting layer 300 includes two regions that respectively emit light of two different wavelengths (i.e., the region of the second epitaxial structure 310 and the region of the third epitaxial structure 320). Then, step S160 is performed, which is a connection process to form a conductive circuit on the first light-emitting layer 200a and the second light-emitting layer 300, such as forming the trace layer 302 as shown in FIG. 2B, or forming the conductive vias 2143b and 2144b as shown in FIG. 3B.

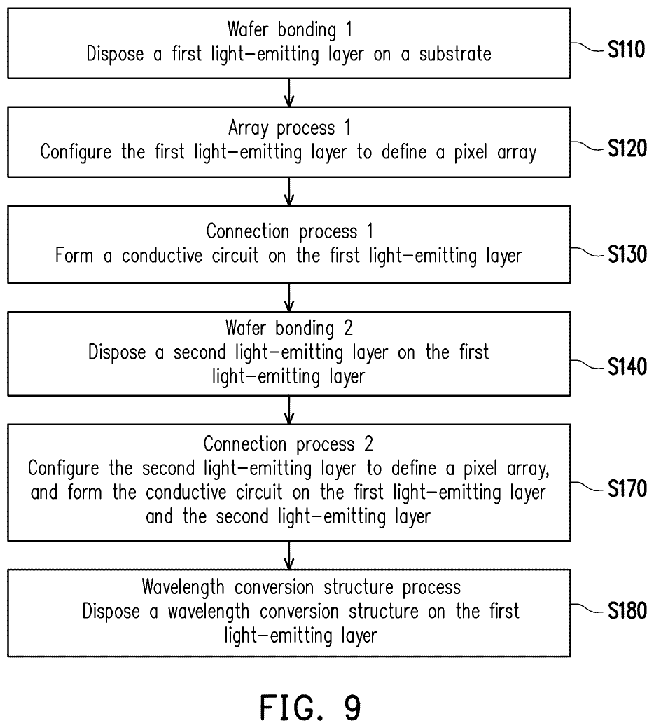

FIG. 9 is a flowchart of a manufacturing method of a micro light-emitting device according to another embodiment of the disclosure. Referring to FIG. 9, the manufacturing method of the micro light-emitting device of the embodiment can be configured to manufacture the micro light-emitting devices 100d to 100f of the embodiments of FIG. 4A to FIG. 6B. In the following, the manufacturing of the micro light-emitting device 100e of FIG. 5A and FIG. 5B is mainly taken as an example for description. The manufacturing method of the micro light-emitting device of the embodiment from steps S110 to S140 is similar to the embodiment of FIG. 8 and therefore is not repeated here. Instead, different steps S170 and S180 will be described below. In step S170, a connection process is performed to configure the second light-emitting layer 300d to define a pixel array (such as the second epitaxial structure 310d of FIG. 5B), and form the conductive circuit on the first light-emitting layer 200e and the second light-emitting layer 300d (such as the trace layer 302e or the conductive vias 2141e and 2142e of FIG. 5B). Then, step S180 is performed, which is a wavelength conversion structure manufacturing process to dispose the wavelength conversion structure 120 on the first light-emitting layer 200e.

To sum up, in the micro light-emitting device display apparatus according to the embodiment of the disclosure, since a stacked structure of the first light-emitting layer and the second light-emitting layer is adopted, and the second light-emitting layer can emit light of two different wavelengths, the spatial resolution of the display pixel can be improved while the space required for the circuit wiring can be reduced to increase the light-emitting area. In addition, in the micro light-emitting device display apparatus according to the embodiment of the disclosure, the sum of the orthographic projection areas of the second epitaxial structure and the third epitaxial structure is less than the orthographic projection area of the first epitaxial structure, or the orthographic projection area of second epitaxial structure is less than the orthographic projection area of the first part, so the sub-pixels in the second light-emitting layer only cover a part of the sub-pixels in the first light-emitting layer such that the light-emitting efficiency can be improved. Furthermore, in the micro light-emitting device display apparatus according to the embodiment of the disclosure, the second epitaxial structure and the third epitaxial structure can be simultaneously disposed on the first light-emitting layer in a single process step through the metal layer. Compared with the requirement of two yellow photolithography processes to define the epitaxial region when separately manufacturing the second epitaxial structure and the third epitaxial structure, it is possible to reduce a one-time alignment step, and connect the first light-emitting layer and the second light-emitting layer by bonding, thereby reducing the impact of alignment tolerances during vertical stacking.

What is claimed is:

1. A micro light-emitting device display apparatus, comprising a plurality of micro light-emitting devices, wherein each micro light-emitting device comprises:
a first light-emitting layer, comprising a first epitaxial structure configured to emit light of a first wavelength; and
a second light-emitting layer, bonded and stacked onto the first light-emitting layer through a metal layer, wherein the second light-emitting layer comprises:
a second epitaxial structure, configured to emit light of a second wavelength; and
a third epitaxial structure, configured to emit light of a third wavelength,
wherein the second epitaxial structure and the third epitaxial structure are nanorod arrays of a same epitaxial material, the third wavelength is greater than the second wavelength, both the second wavelength and the third wavelength are less than the first wavelength, and a sum of orthographic projection areas of the second epitaxial structure and the third epitaxial structure is less than an orthographic projection area of the first epitaxial structure.

2. The micro light-emitting device display apparatus according to claim 1, wherein an indium concentration of the second epitaxial structure is greater than an indium concentration of the third epitaxial structure, and a diameter of a single nanorod in the nanorod array of the second epitaxial structure is greater than a diameter of a single nanorod in the nanorod array of the third epitaxial structure.

3. The micro light-emitting device display apparatus according to claim 1, wherein the orthographic projection area of the second epitaxial structure is less than ½ times the orthographic projection area of the first epitaxial structure, and the orthographic projection area of the third epitaxial structure is less than ½ times the orthographic projection area of the first epitaxial structure.

4. The micro light-emitting device display apparatus according to claim 1, further comprising a substrate configured on a side away from the first light-emitting layer, wherein the first epitaxial structure of the first light-emitting layer has a conductive via configured to electrically connect in a vertical direction an external pad on the substrate and a side of the first epitaxial structure close to the second light-emitting layer.

5. The micro light-emitting device display apparatus according to claim 4, wherein an orthographic projection of the conductive via at least partially overlaps an orthographic projection of the external pad.

6. The micro light-emitting device display apparatus according to claim 4, wherein the first light-emitting layer has another conductive via configured to electrically connect in a vertical direction another external pad on the substrate and the second light-emitting layer.

7. The micro light-emitting device display apparatus according to claim 6, wherein an orthographic projection of the conductive via at least partially overlaps an orthographic projection of the external pad.

8. The micro light-emitting device display apparatus according to claim 4, wherein the second epitaxial structure has another conductive via configured to electrically connect in a vertical direction another external pad on the substrate and a side of the second epitaxial structure away from the first light-emitting layer.

9. The micro light-emitting device display apparatus according to claim 8, wherein the conductive via of the second epitaxial structure is electrically connected to the another external pad on the substrate through the conductive via of the first epitaxial structure.

10. The micro light-emitting device display apparatus according to claim 1, wherein the third epitaxial structure has yet another conductive via configured to electrically connect in a vertical direction yet another external pad on the substrate and a side of the third epitaxial structure away from the first light-emitting layer.

11. The micro light-emitting device display apparatus according to claim 10, wherein the yet another conductive via of the third epitaxial structure is electrically connected to the yet another external pad on the substrate through the conductive via of the first epitaxial structure.

12. The micro light-emitting device display apparatus according to claim 1, wherein the metal layer is disposed in a region where the second epitaxial structure or the third epitaxial structure is bonded onto the first epitaxial structure such that a part of a light-emitting surface of the first epitaxial structure is exposed.

13. A micro light-emitting device display apparatus, comprising:
a first light-emitting layer, comprising a first epitaxial structure having a first part and a second part that emit light of a first wavelength;
a second light-emitting layer, stacked onto the first light-emitting layer, wherein the second light-emitting layer comprises a second epitaxial structure bonded onto the first part through a metal layer and emitting light of a second wavelength; and
a wavelength conversion structure, stacked onto the second part, and configured to convert the light of the first wavelength emitted by the second part into light of a third wavelength,
wherein an orthographic projection area of the second epitaxial structure is less than an orthographic projection area of the first part.

14. The micro light-emitting device display apparatus according to claim 13, further comprising a substrate configured on a side away from the first light-emitting layer, wherein the first light-emitting layer has a conductive via configured to electrically connect in a vertical direction an external pad on the substrate and a side of the first epitaxial structure close to the second light-emitting layer.

15. The micro light-emitting device display apparatus according to claim 14, wherein the first light-emitting layer has another conductive via configured to electrically connect in a vertical direction another external pad on the substrate and the second light-emitting layer.

16. The micro light-emitting device display apparatus according to claim 15, wherein the conductive via and the another conductive via are configured on a side of the first part or the second part.

17. The micro light-emitting device display apparatus according to claim 13, wherein an orthographic projection area of the wavelength conversion structure covers an orthographic projection area of the second part.

18. The micro light-emitting device display apparatus according to claim 13, wherein the first part and the second part of the first epitaxial structure are electrically independent of each other.
